(19) United States
(12) Patent Application Publication
(10) Pub. No.: US 2025/0273459 A1
(43) Pub. Date: Aug. 28, 2025

(54) METHOD OF MANUFACTURING SEMICONDUCTOR DEVICE

(71) Applicant: Renesas Electronics Corporation, Tokyo (JP)

(72) Inventors: Yoshiki YAMAMOTO, Tokyo (JP); Mototsugu YURA, Tokyo (JP)

(21) Appl. No.: 18/961,669

(22) Filed: Nov. 27, 2024

(30) Foreign Application Priority Data
Feb. 27, 2024 (JP) 2024-027608

(51) Int. Cl. H01L 21/02; H01L 21/762; H10D 30/01; H10D 64/01

(52) U.S. Cl. CPC H01L 21/02334; H01L 21/02238; H01L 21/02271; H01L 21/76283; H10D 30/0415; H10D 64/015

(57) ABSTRACT

A first stacked structure and a first sidewall spacer are formed in a first region. A second stacked structure including a metal film is formed in a second region. In the first region, an epitaxial layer is formed on a semiconductor layer. The first sidewall spacer is removed. A first silicon oxide film is formed on a surface of the epitaxial layer exposed from a first insulating film. A thickness of each of the first insulating film and the first silicon oxide film is reduced by performing a cleaning treatment using an aqueous solution containing ammonia and an activator on each of the first insulating film and the first silicon oxide film. An extension region is formed in each of the semiconductor layer and the epitaxial layer by performing an ion implantation so as to pass through each of the first insulating film and the first silicon oxide film.

### CROSS-REFERENCE TO RELATED APPLICATIONS

The disclosure of Japanese Patent Application No. 2024-027608 filed on Feb. 27, 2024 including the specification, drawings and abstract is incorporated herein by reference in its entirety.

### BACKGROUND

The present invention relates to a method of manufacturing a semiconductor device, and for example, relates to a method of manufacturing a semiconductor device including an SOI substrate.

As a semiconductor device for low power consumption, there is a technique of forming a metal insulator semiconductor field effect transistor (MISFET) on a silicon on insulator (SOI) substrate including a semiconductor substrate, an insulating layer formed on the semiconductor substrate, and a semiconductor layer formed on the insulating layer. The MISFET formed on the SOI substrate can reduce parasitic capacitance caused by a diffusion region formed in the semiconductor layer. Therefore, it is possible to improve an operation speed of the MISFET and to reduce power consumption.

There are disclosed techniques listed below.

[Patent Document 1] Japanese Unexamined Patent Application Publication No. 2013-219181

For example, Patent Document 1 discloses a method of manufacturing a semiconductor device using an SOI substrate. First, a gate electrode is formed on a semiconductor layer. Next, a silicon oxide film is formed on the semiconductor layer so as to cover the gate electrode. Next, a dummy sidewall spacer is formed on a side surface of the gate electrode and on the semiconductor layer via the silicon oxide film. Next, an epitaxial layer is formed on the semiconductor layer exposed from the dummy sidewall spacer and the silicon oxide film. Next, the dummy sidewall spacer is removed.

Next, by performing an ion implantation so as to pass through the silicon oxide film located on the semiconductor layer, an extension region is formed in the semiconductor layer. Next, a sidewall spacer is formed again on the side surface of the gate electrode. Next, by performing the ion implantation, a diffusion region is formed in the epitaxial layer exposed from the sidewall spacer.

### SUMMARY

As described above, when the extension region is formed, an ion implantation is performed so as to pass through the silicon oxide film. However, in a case where the thickness of the silicon oxide film is too large, it may be difficult to implant ions into the semiconductor layer. Therefore, the present inventors have examined adjusting the thickness of the silicon oxide film by a cleaning treatment before forming the extension region. In addition, in recent years, a MISFET has been developed in which a metal film such as a titanium nitride film functions as a part of a gate electrode.

The inventors of the present application have examined that a MISFET including a metal film is mixedly mounted on a semiconductor device using an SOI substrate. In the process, it has been found that the metal film may be etched depending on an aqueous solution used in the cleaning treatment for adjusting the thickness of the silicon oxide film.

On the other hand, a dummy sidewall spacer is removed after an epitaxial layer is formed, but the epitaxial layer covered with the dummy sidewall spacer is exposed when the cleaning treatment is performed. Here, the metal film is hardly etched, but the exposed epitaxial layer may be easily etched depending on an aqueous solution used in the cleaning treatment.

Therefore, there is a demand for a technique in which both a metal film and an epitaxial layer are not etched even when a MISFET including the metal film is mixedly mounted on a semiconductor device using an SOI substrate. Therefore, a technique capable of improving reliability of a semiconductor device is required.

Other problems and novel features will be apparent from the description of the present specification and the attached drawings.

A method of manufacturing a semiconductor device according to an embodiment is a method of manufacturing a semiconductor device having a first region in which a first MISFET is formed and a second region in which a second MISFET is formed. The method of manufacturing the semiconductor device includes: in the first region, forming a first stacked structure and a first sidewall spacer; in the second region, forming a second stacked structure including a metal film; in the second region, forming an epitaxial layer on the semiconductor layer exposed from the first stacked structure, a first insulating film, and the first sidewall spacer in the first region; removing the first sidewall spacer in the first region and removing a second insulating film;

in the first region, forming a first silicon oxide film on a surface of the epitaxial layer exposed from the first insulating film; reducing the thickness of each of the first insulating film and the first silicon oxide film by performing a cleaning treatment on the first insulating film and the first silicon oxide film using an aqueous solution containing ammonia and an activator; and forming a first impurity region in each of the semiconductor layer and the epitaxial layer by performing an ion implantation so as to pass through each of the first insulating film and the first silicon oxide film in the first region.

A method of manufacturing a semiconductor device according to an embodiment includes: forming a first stacked structure including a metal film on a semiconductor layer; forming an epitaxial layer on the semiconductor layer; forming a first silicon oxide film on a surface of the epitaxial layer exposed from a first insulating film; reducing the thickness of each of the first insulating film and the first silicon oxide film by performing a cleaning treatment on the first insulating film and the first silicon oxide film using an aqueous solution containing ammonia and an activator; and forming a first impurity region in each of the semiconductor layer and the epitaxial layer by performing an ion implantation so as to pass through each of the first insulating film and the first silicon oxide film.

According to an embodiment, reliability of a semiconductor device can be improved.

### BRIEF DESCRIPTION OF THE DRAWINGS

FIG. 1 is a cross-sectional view illustrating a semiconductor device in a first embodiment.

FIG. 2 is a cross-sectional view illustrating a step of manufacturing the semiconductor device in the first embodiment.

FIG. 3 is a cross-sectional view illustrating a manufacturing step subsequent to FIG. 2.

FIG. 4 is a cross-sectional view illustrating a manufacturing step subsequent to FIG. 3.

FIG. 5 is a cross-sectional view illustrating a manufacturing step subsequent to FIG. 4.

FIG. 6 is a cross-sectional view illustrating a manufacturing step subsequent to FIG. 5.

FIG. 7 is a cross-sectional view illustrating a manufacturing step subsequent to FIG. 6.

FIG. 8 is a cross-sectional view illustrating a manufacturing step subsequent to FIG. 7.

FIG. 9 is a cross-sectional view illustrating a manufacturing step subsequent to FIG. 8.

FIG. 10 is a cross-sectional view illustrating a manufacturing step subsequent to FIG. 9.

FIG. 11 is a cross-sectional view illustrating a manufacturing step subsequent to FIG. 10.

FIG. 12 is a cross-sectional view illustrating a manufacturing step subsequent to FIG. 11.

FIG. 13 is a cross-sectional view illustrating a manufacturing step subsequent to FIG. 12.

FIG. 14 is a cross-sectional view illustrating a manufacturing step subsequent to FIG. 13.

FIG. 15 is a cross-sectional view illustrating a manufacturing step subsequent to FIG. 14.

FIG. 16 is a cross-sectional view illustrating a manufacturing step subsequent to FIG. 15.

FIG. 17 is a cross-sectional view illustrating a manufacturing step subsequent to FIG. 16.

FIG. 18 is a cross-sectional view illustrating a step of manufacturing a semiconductor device in a modification.

FIG. 19 is a cross-sectional view illustrating a manufacturing step subsequent to FIG. 18.

FIG. 20 is a cross-sectional view illustrating a manufacturing step subsequent to FIG. 19.

FIG. 21 is a cross-sectional view illustrating a manufacturing step subsequent to FIG. 20.

FIG. 22 is a cross-sectional view illustrating a manufacturing step subsequent to FIG. 21.

FIG. 23 is a cross-sectional view illustrating a semiconductor device in a second embodiment.

FIG. 24 is a sectional illustrating a step of manufacturing the semiconductor device in the second embodiment.

FIG. 25 is a cross-sectional view illustrating a manufacturing step subsequent to FIG. 24.

FIG. 26 is a cross-sectional view illustrating a manufacturing step subsequent to FIG. 25.

FIG. 27 is a cross-sectional view illustrating a manufacturing step subsequent to FIG. 26.

FIG. 28 is a cross-sectional view illustrating a manufacturing step subsequent to FIG. 27.

FIG. 29 is a cross-sectional view illustrating a manufacturing step subsequent to FIG. 28.

FIG. 30 is a cross-sectional view illustrating a manufacturing step subsequent to FIG. 29.

FIG. 31 is a cross-sectional view illustrating a step of manufacturing a semiconductor device in an examined example.

### DETAILED DESCRIPTION

Hereinafter, embodiments will be described in detail with reference to the drawings. Note that, in all the drawings for describing the embodiments, members having the same functions are denoted by the same reference numerals, and repeated description thereof will be omitted. In addition, in the following embodiments, descriptions of the same or similar parts will not be repeated in principle unless particularly necessary.

### First Embodiment

First, a part of a structure of a semiconductor device in a first embodiment will be described with reference to FIG. 1. As illustrated in FIG. 1, the semiconductor device includes an SOI substrate 10. The SOI substrate 10 includes a semiconductor substrate SUB, an insulating layer BOX formed on the semiconductor substrate SUB, and a semiconductor layer SL formed on the insulating layer BOX. In addition, the semiconductor device has a region 1A and a region 2A located around the region 1A.

The region 1A is an SOI region in which the insulating layer BOX and the semiconductor layer SL are left. A MISFET 1Q is formed in the region 1A. The MISFET 10 is a low breakdown voltage MISFET constituting a logic circuit, an SRAM circuit, and the like. FIG. 1 illustrates a case where the MISFET 10 is an n-type low breakdown voltage MISFET.

The region 2A is a bulk region from which the insulating layer BOX and the semiconductor layer SL have been removed. In the region 2A, a ferroelectric memory transistor MQ is formed as an n-type MISFET. Although not illustrated, a high breakdown voltage MISFET that constitutes an I/O circuit or the like and has a higher breakdown voltage than the low breakdown voltage MISFET of the region 1A is also formed in a bulk region such as the region 2A.

The ferroelectric memory transistor MQ is an electrically rewritable nonvolatile memory cell. The ferroelectric memory transistor MQ includes a ferroelectric film FE, and can change a write state and an erase state by controlling a polarization direction of the ferroelectric film FE.

In addition, the ferroelectric memory transistor MQ includes a metal film MF and a gate electrode GE2. The metal film MF applies stress to the ferroelectric film FE during manufacturing steps, and controls a crystal orientation of the ferroelectric film FE. That is, the metal film MF has a function of orienting a crystal phase of the ferroelectric film FE into an orthorhombic crystal. In addition, the metal film MF also functions as a part of the gate electrode GE2.

### <Method of Manufacturing Semiconductor Device>

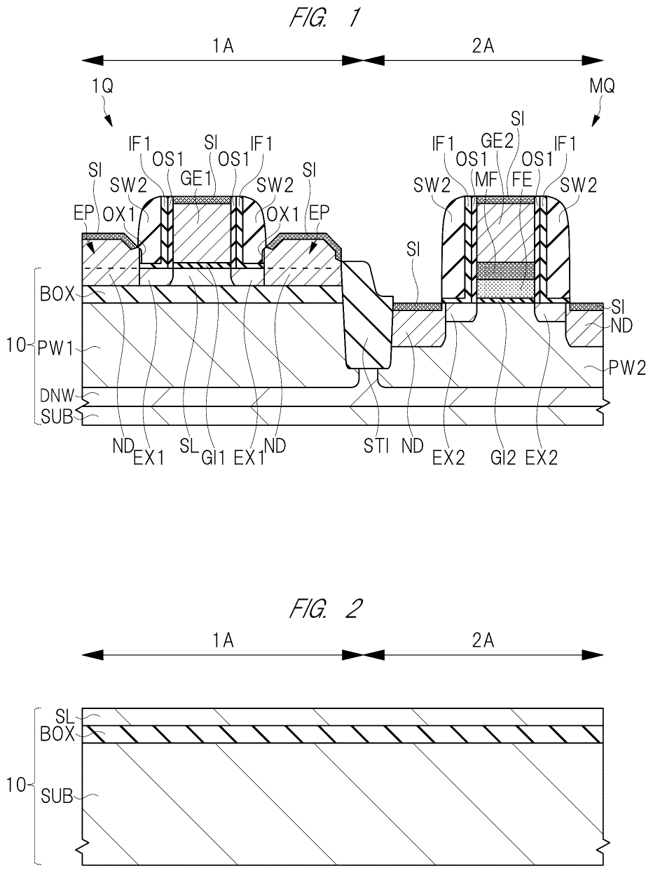

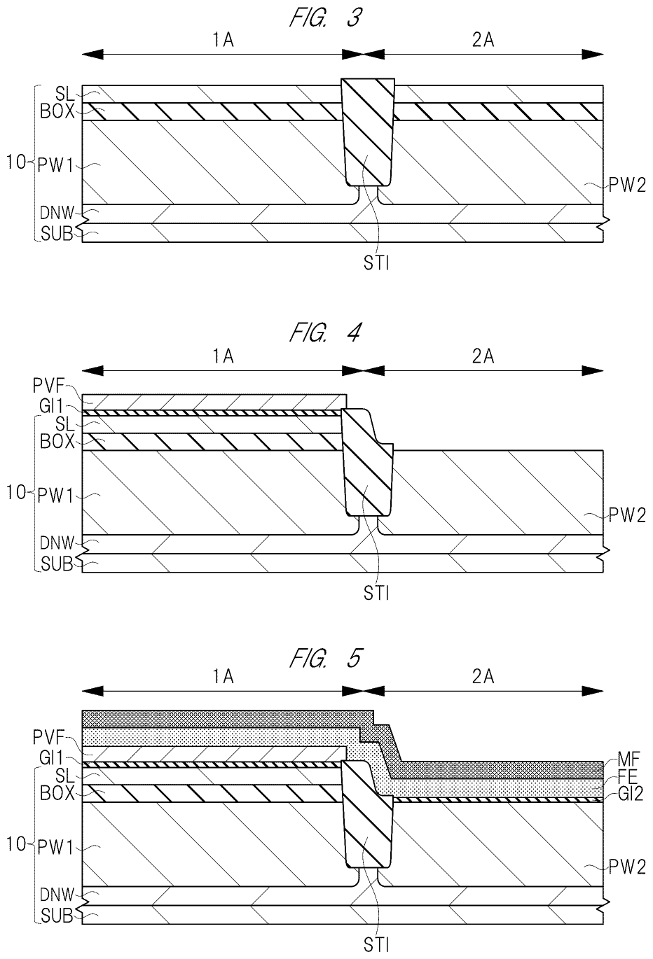

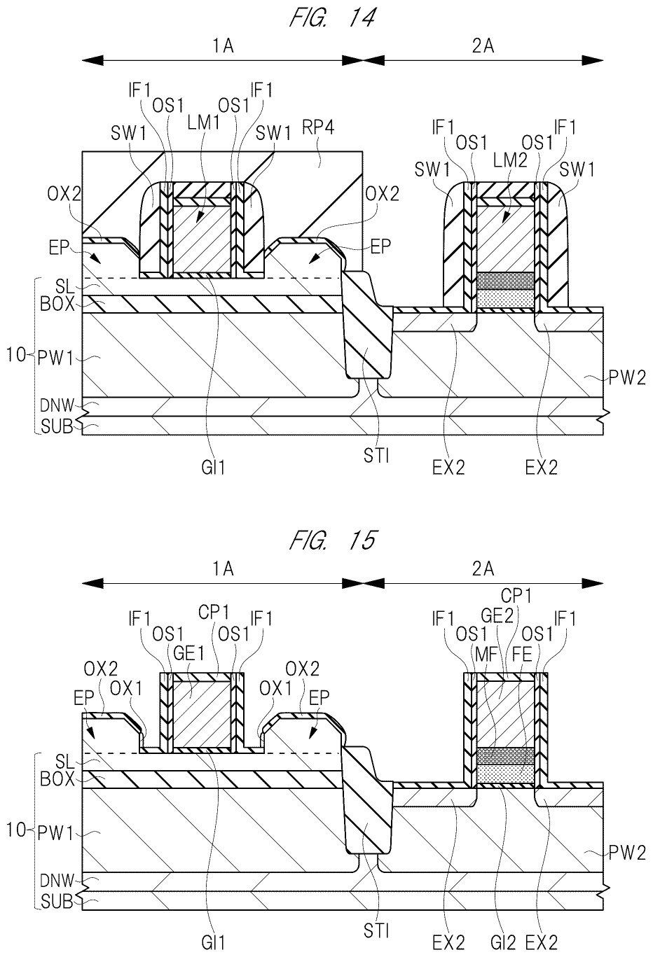

Each manufacturing step in a method of included manufacturing the semiconductor device in the first embodiment will be described below with reference to FIGS. 2 to 17.

First, as illustrated in FIG. 2, the SOI substrate 10 including the semiconductor substrate SUB, the insulating layer BOX formed on the semiconductor substrate SUB, and the semiconductor layer SL formed on the insulating layer BOX is prepared.

The semiconductor substrate SUB is made of, for example, p-type single crystal silicon. The insulating layer BOX is made of, for example, silicon oxide, and has a thickness of, for example, 10 nm or more and 20 nm or less. The semiconductor layer SL is made of single crystal silicon and has a thickness of, for example, 10 nm or more and 20 nm or less. Note that the semiconductor layer SL is an intrinsic semiconductor layer into which n-type or p-type impurities are not introduced by an ion implantation or the like. Even when p-type impurities are introduced into the semiconductor layer SL, an impurity concentration thereof is 1×10¹³/cm³ or less.

Such an SOI substrate 10 is formed by, for example, a bonding method. In the bonding method, for example, a surface of a first semiconductor substrate made of silicon is oxidized to form an insulating layer BOX, and then a second semiconductor substrate made of silicon is pressure-bonded onto the insulating layer BOX at a high temperature. Thereafter, the second semiconductor substrate is thinned. The thin film of the second semiconductor substrate remaining on the insulating layer BOX is formed as the semiconductor layer SL, and the first semiconductor substrate under the insulating layer BOX is formed as the semiconductor substrate SUB.

As illustrated in FIG. 3, an element isolation portion STI, an n-type well region DNW, a p-type well region PW1, and a p-type well region PW2 are formed.

First, a groove reaching the semiconductor substrate SUB is formed in the SOI substrate 10 using a photolithography technique and an etching treatment. Next, an insulating film is formed so as to fill the inside of the groove by a film forming treatment using, for example, a chemical vapor deposition (CVD) method. Next, the insulating film located outside the groove is removed by a polishing treatment using a chemical mechanical polishing (CMP) method. As described above, the element isolation portion STI including the groove and the insulating film is formed. Note that the depth of the element isolation portion STI is, for example, 300 nm or more and 400 nm or less.

Next, a well region (impurity region) DNW is formed in the semiconductor substrate SUB by a photolithography technique and an ion implantation method. Next, by a photolithography technique and an ion implantation method, a well region (impurity region) PW1 is formed in the well region DNW of the region 1A and a well region (impurity region) PW2 is formed in the well region DNW of the region 2A.

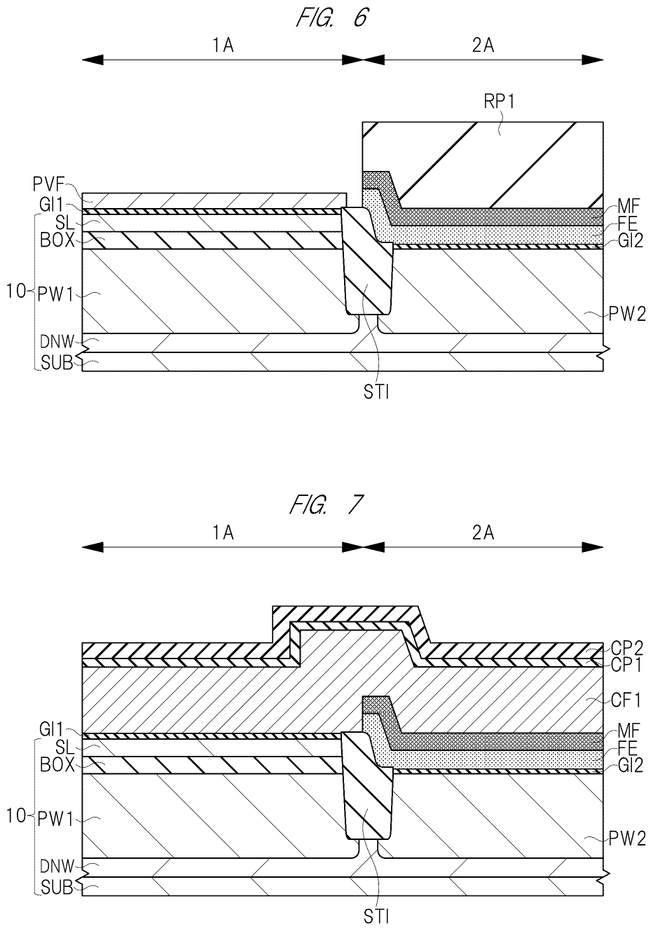

As illustrated in FIG. 4, the semiconductor layer SL and the insulating layer BOX located in the region 2A are selectively removed, and a gate insulating film GI1 and a protective film PVF are formed on the semiconductor layer SL located in the region 1A.

First, the semiconductor layer SL and the insulating layer BOX located in the region 2A are selectively removed using a photolithography technique and an etching treatment so as to leave the semiconductor layer SL and the insulating layer BOX located in the region 1A. As a result, the semiconductor substrate SUB located in the region 2A is exposed.

Next, the gate insulating film GI1 is formed on the semiconductor layer SL located in the region 1A and on the semiconductor substrate SUB located in the region 2A by a thermal oxidation treatment. The gate insulating film GI1 is, for example, a silicon oxide film, and has a thickness of, for example, 2 nm or more and 5 nm or less. Next, the gate insulating film GI1 located in the region 2A is selectively removed using a photolithography technique and an etching treatment so as to leave the gate insulating film GI1 located in the region 1A.

Next, the protective film PVF is formed on the gate insulating film GI1 located in the region 1A and on the semiconductor substrate SUB located in the region 2A by a film forming treatment using, for example, a CVD method. The protective film PVF is, for example, a silicon nitride film, a silicon oxynitride film, or a polycrystalline silicon film. Next, the protective film PVF located in the region 2A is selectively removed using a photolithography technique and an etching treatment so as to leave the protective film PVF located in the region 1A. As a result, the semiconductor substrate SUB located in the region 2A is exposed.

As illustrated in FIG. 5, a gate insulating film GI2, the ferroelectric film FE, and the metal film MF are formed.

First, the gate insulating film GI2 is formed on the semiconductor substrate SUB located in the region 2A by a thermal oxidation treatment using an in situ steam generation (ISSG) oxidation method. The gate insulating film GI2 is, for example, a silicon oxide film, and has a thickness of, for example, 1 nm or more and 5 nm or less.

Next, the ferroelectric film FE is formed on the protective film PVF located in the region 1A and on the gate insulating film GI2 located in the region 2A by a film forming treatment using, for example, an atomic layer deposition (ALD) method. Note that the ferroelectric film FE at this time is in an amorphous state.

The ferroelectric film FE is an HfO₂ film or an HfO₂ film to which at least one of zirconium (Zr), silicon (Si), nitrogen (N), carbon (C), and aluminum (Al) is added. The ferroelectric film FE has a thickness of, for example, 4 nm or more and 20 nm or less.

Next, the metal film MF is formed on the ferroelectric films FE located in the region 1A and the region 2A by a film forming treatment using, for example, a CVD method or a sputtering method. The metal film MF is, for example, a titanium nitride film. The metal film MF has a thickness of, for example, 10 nm or more and 20 nm or less.

Next, the ferroelectric film FE is crystallized by a heat treatment to form an orthorhombic ferroelectric film FE. This heat treatment is performed within a temperature range of 400° C. or higher and 600° C. or lower. Here, the metal film MF applies stress to the ferroelectric film FE during the heat treatment, and controls a crystal orientation of the ferroelectric film FE. That is, the metal film MF has a function of orienting a crystal phase of the ferroelectric film FE into an orthorhombic crystal.

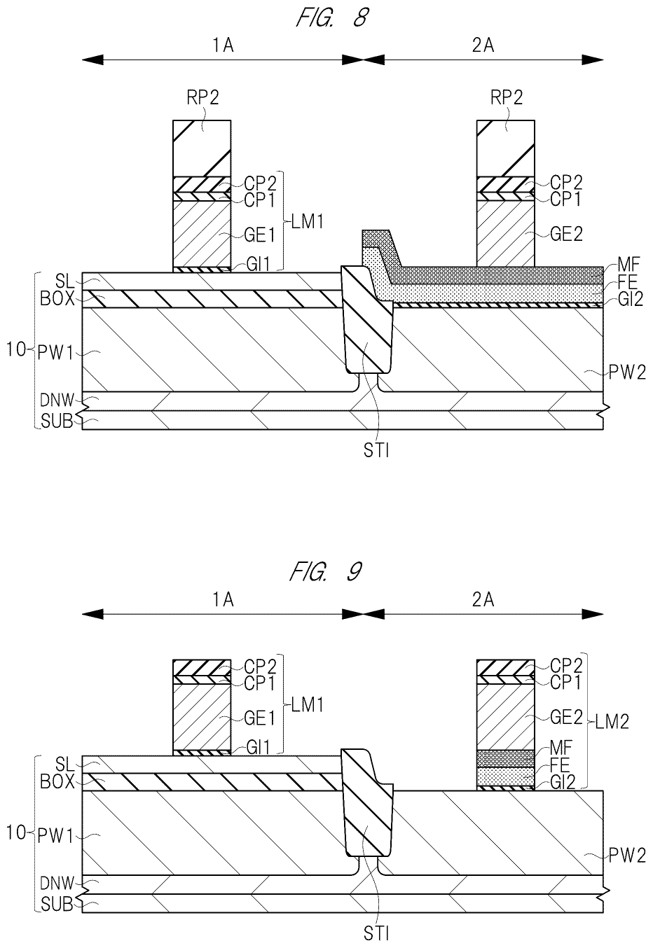

As illustrated in FIG. 6, the metal film MF and the ferroelectric film FE located in the region 1A are selectively removed.

First, a resist pattern RP1 that opens the region 1A and covers the region 2A is formed on the metal film MF. Next, by performing an anisotropic etching treatment using the resist pattern RP1 as a mask, the metal film MF and the ferroelectric film FE exposed from the resist pattern RP1 are removed. Next, the resist pattern RP1 is removed by an ashing treatment.

Note that, in the anisotropic etching treatment, over-etching is performed such that the metal film MF and the ferroelectric film FE located in the region 1A are reliably removed. The protective film PVF protects the gate insulating film GI1 from this over-etching.

As illustrated in FIG. 7, the protective film PVF is removed, and a conductive film CF1, a cap film CP1, and a cap film CP2 are formed.

First, by performing an etching treatment using the metal film MF and the ferroelectric film FE as a mask, the protective film PVF located in the region 1A is removed. Next, the conductive film CF1, the cap film CP1, and the cap film CP2 are sequentially formed on the gate insulating film GI1 located in the region 1A and on the metal film MF located in the region 2A by a film forming treatment using, for example, a CVD method.

The conductive film CF1 is, for example, an n-type polycrystalline silicon film, and has a thickness of, for example, 60 nm or more and 100 nm or less. The cap film CP1 is, for example, an insulating film such as a silicon oxide film, and has a thickness of, for example, 5 nm or more and 10 nm or less. The cap film CP2 is an insulating film such as a silicon nitride film, and has a thickness of, for example, 10 nm or more and 20 nm or less.

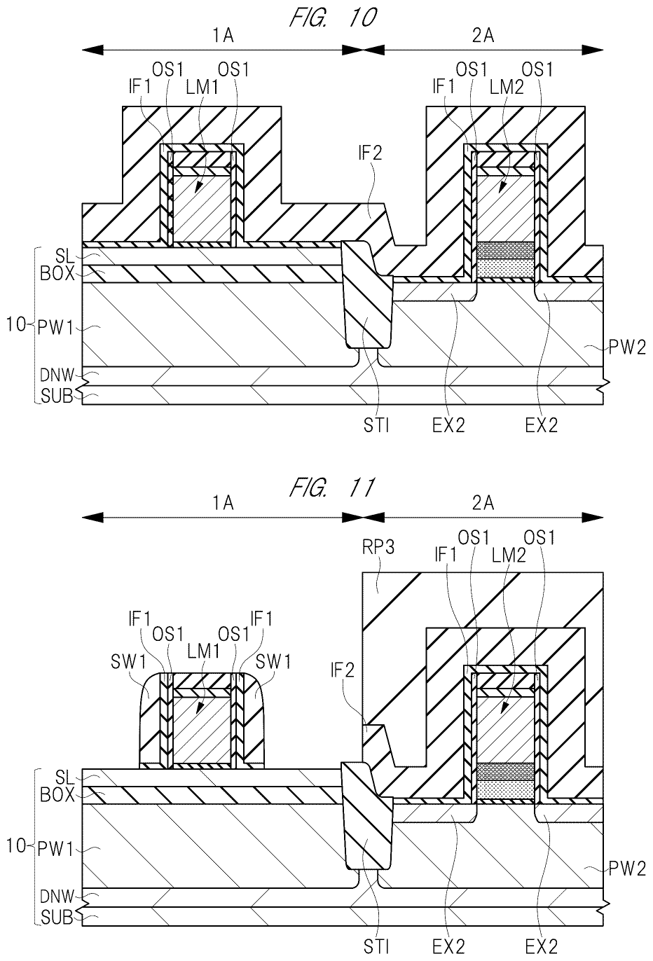

As illustrated in FIG. 8, the conductive film CF1, the cap film CP1, and the cap film CP2 are patterned.

First, in the region 1A and the region 2A, a resist pattern RP2 is formed so as to cover a part of the cap film CP2. Next, by performing an anisotropic etching treatment using the resist pattern RP2 as a mask, the cap film CP2, the cap film CP1, and the conductive film CF1 exposed from the resist pattern RP2 are removed. Next, the resist pattern RP2 is removed by an ashing treatment.

The patterned conductive film CF1 is formed as a gate electrode GE1 in the region 1A and formed as a gate electrode GE2 in the region 2A. Next, by performing an isotropic etching treatment using an aqueous solution containing hydrofluoric acid, the gate insulating film GI1 exposed from the gate electrode GE1 in the region 1A may be removed.

In this manner, a stacked structure LM1 including the gate insulating film GI1, the gate electrode GE1, the cap film CP1, and the cap film CP2 is formed on the semiconductor layer SL located in the region 1A.

As illustrated in FIG. 9, by performing an anisotropic etching treatment using the cap film CP2 as a mask, the metal film MF and the ferroelectric film FE exposed from the cap film CP2 in the region 2A are removed. Next, by performing an isotropic etching treatment using an aqueous solution containing hydrofluoric acid, the gate insulating film GI2 exposed from the ferroelectric film FE in the region 2A may be removed.

In this manner, a stacked structure LM2 including the gate insulating film GI2, the ferroelectric film FE, the metal film MF, the gate electrode GE2, the cap film CP1, and the cap film CP2 is formed on the semiconductor substrate SUB located in the region 2A.

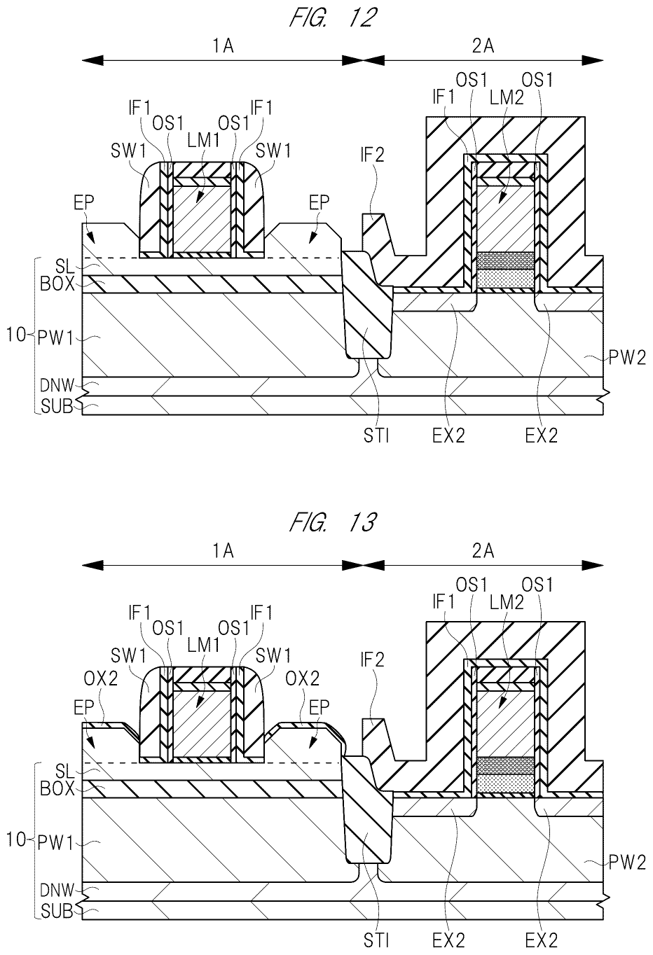

As illustrated in FIG. 10, an offset spacer OS1, an extension region EX2, an insulating film IF1, and an insulating film IF2 are formed.

First, a silicon nitride film is formed by a film forming treatment using, for example, a CVD method so as to cover the stacked structure LM1 and the stacked structure LM2. Next, by processing the silicon nitride film by an anisotropic etching treatment, the offset spacer OS1 is formed on a side surface of each of the stacked structure LM1 and the stacked structure LM2.

Next, the n-type extension region (impurity region) EX2 is selectively formed in the well region PW2 (in the semiconductor substrate SUB) in the region 2A by a photolithography technique and an ion implantation method.

Next, the insulating film IF1 is formed by a film forming treatment using, for example, a CVD method so as to cover the stacked structure LM1 and the stacked structure LM2. Next, the insulating film IF2 is formed on the insulating film IF1 by a film forming treatment using, for example, a CVD method in the region 1A and the region 2A.

The insulating film IF1 is, for example, a silicon oxide film, and has a thickness of, for example, 5 nm or more and 10 nm or less. The insulating film IF2 is, for example, a silicon nitride film, and has a thickness of, for example, 30 nm or more and 50 nm or less.

As illustrated in FIG. 11, a sidewall spacer SW1 is formed from the insulating film IF2 in the region 1A.

First, a resist pattern RP3 that covers the insulating film IF2 located in the region 2A and opens the insulating film IF2 located in the region 1A is formed. Next, an anisotropic etching treatment is performed on the insulating film IF2 located in the region 1A using the resist pattern RP3 as a mask. By selectively processing the insulating film IF2 in the region 1A, the sidewall spacer SW1 is formed on a side surface of the stacked structure LM1 via the offset spacer OS1 and the insulating film IF1. Next, the resist pattern RP3 is removed by an ashing treatment. Next, by performing an isotropic etching treatment using an aqueous solution containing hydrofluoric acid, the insulating film IF1 exposed from the sidewall spacer SW1 in the region 1A is removed.

As illustrated 12, in an epitaxial layer FIG. (semiconductor layer) EP is formed on the semiconductor layer SL exposed from the stacked structure LM1, the insulating film IF1, and the sidewall spacer SW1 in the region 1A by a film forming treatment using an epitaxial growth method. At this time, since the region 1A on the gate electrode GE1 is covered with the cap film CP2 and the entire region 2A is covered with the insulating film IF2, the epitaxial layer EP is not formed at these places.

Note that the epitaxial layer EP is made of, for example, single crystal silicon, which is the same material as that of the semiconductor layer SL, and therefore the epitaxial layer EP is integrated with the semiconductor layer SL. However, in order to facilitate understanding of the invention, a boundary between the epitaxial layer EP and the semiconductor layer SL is indicated by a broken line in the following drawings.

As illustrated in FIG. 13, a silicon oxide film OX2 is formed on a surface of the epitaxial layer EP exposed from the sidewall spacer SW1 in the region 1A by a thermal oxidation treatment. The silicon oxide film OX2 has a thickness of, for example, 3 nm or more and 10 nm or less.

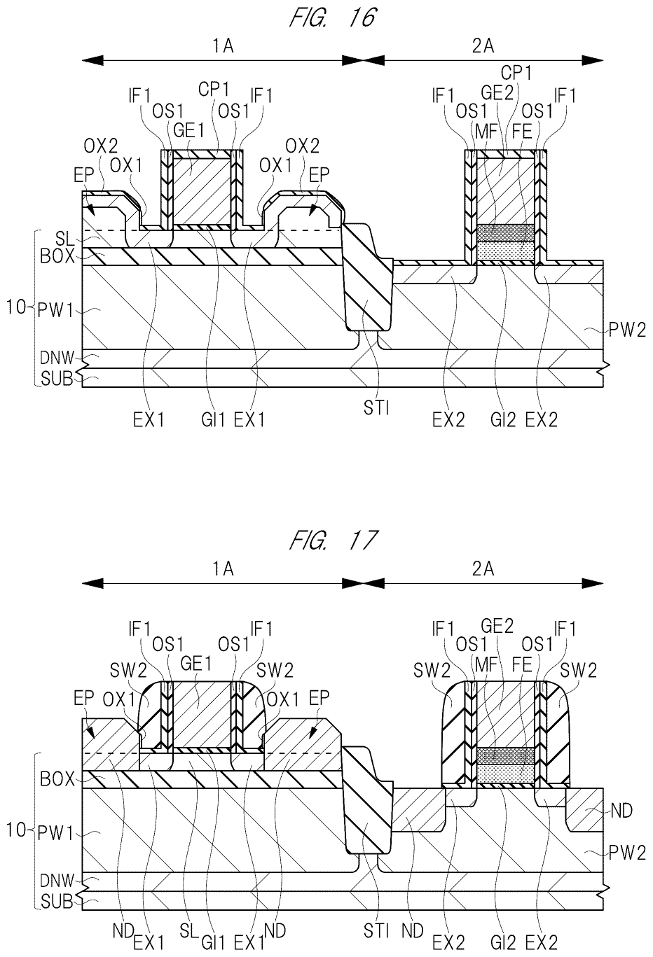

As illustrated in FIG. 14, the sidewall spacer SW1 is formed from the insulating film IF2 in the region 2A.

First, a resist pattern RP4 that covers the region 1A and opens the insulating film IF2 located in the region 2A is formed. Next, an anisotropic etching treatment is performed on the insulating film IF2 located in the region 2A using the resist pattern RP4 as a mask. By selectively processing the insulating film IF2 in the region 2A, the sidewall spacer SW1 is formed on a side surface of the stacked structure LM2 via the offset spacer OS1 and the insulating film IF1. Next, the resist pattern RP4 is removed by an ashing treatment.

As illustrated in FIG. 15, the sidewall spacer SW1 made of the insulating film IF2 is removed, and a silicon oxide film OX1 is formed on a surface of the epitaxial layer EP.

First, by performing an anisotropic etching treatment under a condition in which a silicon nitride film is more easily etched than a silicon oxide film, the sidewall spacer SW1 is removed in the region 1A and the region 2A. At this time, the cap film CP2 of each of the stacked structure LM1 and the stacked structure LM2 is also removed. By removing the sidewall spacer SW1, a part of a surface of the epitaxial layer EP in contact with the sidewall spacer SW1 is exposed.

Next, a silicon oxide film OX1 is formed on a surface of the epitaxial layer EP exposed from the insulating film IF1 and the silicon oxide film OX2 in the region 1A. The silicon oxide film OX1 can be formed by, for example, an ashing treatment. In a case where the ashing treatment is used, the silicon oxide film OX1 has a thickness of, for example, 1 nm or more and 2 nm or less. As another example, the silicon oxide film OX1 can be formed by, for example, a thermal oxidation treatment. In a case where the thermal oxidation treatment is used, the silicon oxide film OX1 has a thickness of, for example, 3 nm or more and 10 nm or less.

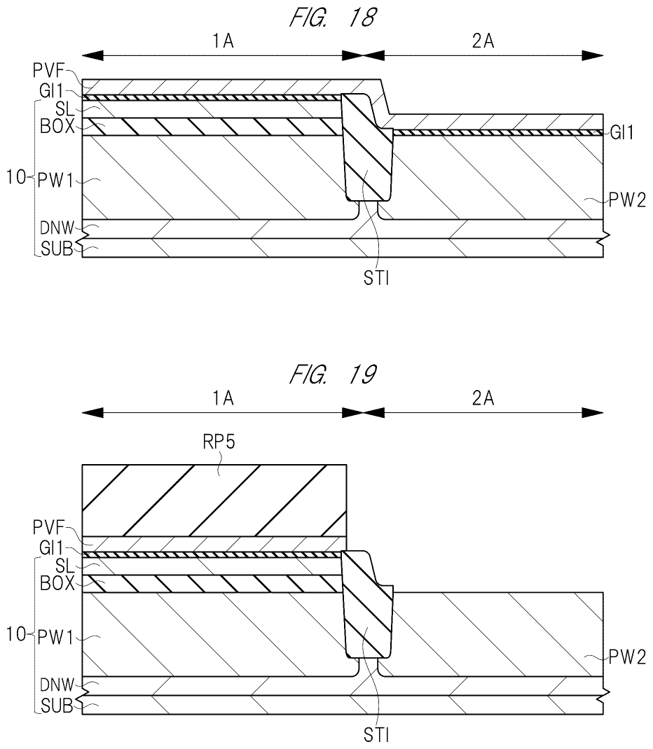

As illustrated in FIG. 16, after the thickness of the insulating film IF1 functioning as a through film at the time of the ion implantation is adjusted by a cleaning treatment, the extension region (impurity region) EX1 is formed by the ion implantation.

When the extension EX1 region is formed in the semiconductor layer SL, the ion implantation is performed so as to pass through the insulating film IF1 (silicon oxide film). However, in a case where the thickness of the insulating film IF1 is too large, it may be difficult to implant ions into the semiconductor layer SL. Therefore, before the extension region EX1 is formed, the thickness of the insulating film IF1 is adjusted by the cleaning treatment.

### <Problems of Examined Example and Main Features of First Embodiment>

Hereinafter, manufacturing steps of an examined example examined by the inventors of the present application will be described with reference to FIG. 31. FIG. 31 illustrates states before and after the above-described cleaning treatment.

First, the inventors of the present application have examined use of an aqueous solution containing ammonia water and hydrogen peroxide water (APM cleaning solution) and an aqueous solution containing hydrofluoric acid and hydrogen peroxide water (HPM cleaning solution) as an aqueous solution to be used for a cleaning treatment. The thickness of the insulating film IF1 can be adjusted by the APM cleaning solution and the HPM cleaning solution.

However, the inventors of the present application have found that when a MISFET (ferroelectric memory transistor MQ) including the metal film MF is present in addition to the MISFET 1Q as in the first embodiment, a problem that a part of the metal film MF is dissolved by the APM cleaning solution and the HPM cleaning solution occurs.

As a cause of this problem, as illustrated in FIG. 15, a side surface of the metal film MF is covered with the offset spacer OS1 and the insulating film IF1, but pinholes (defects) may be locally formed in the offset spacer OS1 and the insulating film IF1. In a case where the offset spacer OS1 and the insulating film IF1 are formed by a film forming treatment using a CVD method, the pinholes are easily formed. Therefore, the APM cleaning solution and the HPM cleaning solution reach the metal film MF via the pinholes, and a problem that a part of the metal film MF is dissolved occurs. In particular, the hydrogen peroxide water contained in the APM cleaning solution and the HPM cleaning solution has a property of easily dissolving the metal film MF.

Therefore, the inventors of the present application considered applying an aqueous solution containing ammonia water and an activator instead of the APM cleaning solution and the HPM cleaning solution. This aqueous solution does not contain hydrogen peroxide water. With this aqueous solution, even when pinholes are formed in the offset spacer OS1 and the insulating film IF1, the problem that a part of the metal film MF is dissolved can be solved. The thickness of a silicon oxide film such as the insulating film IF1 can be adjusted by this aqueous solution, and this aqueous solution has a constant etching rate with respect to silicon.

As illustrated in “Before cleaning treatment” of FIG. 31, when the sidewall spacer SW1 is removed, a part of a surface of the epitaxial layer EP in contact with the sidewall spacer SW1 is exposed. In FIG. 31, a portion where the epitaxial layer EP is exposed is illustrated as a concern portion 20. Here, in the examined example, unlike the first embodiment, the silicon oxide film OX1 is not formed.

As illustrated in “After cleaning treatment” in FIG. 31, when the cleaning t is performed using an aqueous solution containing ammonia water and an activator, etching of silicon proceeds from the concern portion 20, and a part of the epitaxial layer EP and a part of the semiconductor layer SL are removed. As a result, a problem that an on-current of the MISFET 1Q decreases occurs.

Furthermore, an upper portion of each of the offset spacer OS1 and the insulating film IF1 formed on a side surface of the stacked structure LM1 may be retracted by the isotropic etching treatment on the insulating film IF1 in FIG. 11 and the step of removing the sidewall spacer SW1 in FIG. 15. In this case, an upper portion of the gate electrode GE1 is exposed. In FIG. 31, a portion where the upper portion of the gate electrode GE1 is exposed is illustrated as a concern portion 21.

In this state, when the cleaning treatment is performed using an aqueous solution containing ammonia water and an activator, etching of silicon proceeds from the concern portion 21, and a problem that a part of the gate electrode GE1 is removed occurs.

In the first embodiment, as described with reference to FIG. 15, the silicon oxide film OX1 is formed on a surface of the epitaxial layer EP exposed from the insulating film IF1 and the silicon oxide film OX2. Note that, even when the concern portion 21 in FIG. 31 is generated, the silicon oxide film OX1 is also formed above the exposed gate electrode GE1.

That is, by forming the silicon oxide film OX1, there is no portion where silicon is exposed at the time of the cleaning treatment. Therefore, in the first embodiment, the problem that the metal film MF is dissolved can be solved, and the problem that a part of each of the epitaxial layer EP, the semiconductor layer SL, and the gate electrode GE1 is removed can be solved. As a result, reliability of the semiconductor device can be improved.

Note that, in the thickness adjustment by the cleaning treatment using the aqueous solution containing ammonia water and an activator, the thickness of each of the insulating film IF1, the silicon oxide film OX1, and the silicon oxide film OX2 is reduced. In a case where the silicon oxide film OX1 is formed by an ashing treatment, it is difficult to form the silicon oxide film OX1 thick as compared with a case where the silicon oxide film OX1 is formed by a thermal oxidation treatment. Therefore, the silicon oxide film OX1 may be entirely removed in the middle of the cleaning treatment. In such a case, the ashing treatment is performed again to increase the thickness of the silicon oxide film OX1, and the cleaning treatment is performed again. That is, in a case where the silicon oxide film OX1 is formed by the ashing treatment, formation of the silicon oxide film OX1 by the ashing treatment and the cleaning treatment may be repeated a plurality of times.

In a case where the silicon oxide film OX1 is formed by the thermal oxidation treatment, it is easy to form the thick silicon oxide film OX1 as compared with a case where the silicon oxide film OX1 is formed by the ashing treatment. Therefore, since it is not necessary to repeat formation of the silicon oxide film OX1 and the cleaning treatment a plurality of times, the manufacturing steps can be simplified.

On the other hand, in a case where the silicon oxide film OX1 is formed by the thermal oxidation treatment, a thermal load history increases. In steps of manufacturing a semiconductor device, in a case where the thermal load history is very large, an impurity profile of an impurity region fluctuates, or a defect such as distortion occurs in a semiconductor substrate. Therefore, the thermal load history is preferably as small as possible. In a case where the silicon oxide film OX1 is formed by the ashing treatment, the thermal load history hardly Therefore, the ashing treatment is superior to the increases. thermal oxidation treatment from a viewpoint of such a thermal load history.

As described above, after the formation and the cleaning treatment are performed on the silicon oxide film OX1, as illustrated in FIG. 16, by performing the ion implantation so as to pass through the insulating film IF1, the silicon oxide film OX1, and the silicon oxide film OX2 in the region 1A by a photolithography technique and an ion implantation method, the n-type extension region EX1 is selectively formed in the semiconductor layer SL and the epitaxial layer EP.

As illustrated in FIG. 17, a sidewall spacer SW2 and a diffusion region (impurity region) ND are formed, and the silicon oxide film OX2 and the cap film CP1 are removed.

First, in the region 1A and the region 2A, for example, a silicon nitride film is formed by, for example, a CVD method. By performing an anisotropic etching treatment t on the silicon nitride film, the sidewall spacer SW2 is formed on a side surface of each of the gate electrode GE1 and the gate electrode GE2 via the offset spacer OS1 and the insulating film IF1. Note that the sidewall spacer SW2 is formed so as to cover a part of the epitaxial layer EP. In addition, the sidewall spacer SW2 may be a stacked film of a silicon oxide film and the silicon nitride film formed on the silicon oxide film.

Next, an n-type diffusion region ND is formed in the epitaxial layer EP and the semiconductor layer SL located in the region 1A and in the semiconductor substrate SUB located in the region 2A using a photolithography technique and an ion implantation method. Next, by performing a heat treatment in an inert gas atmosphere, impurities contained in each impurity region such as the diffusion region ND is activated.

In the region 1A, the extension region EX1 and the diffusion region ND constitute a source region or a drain region of the MISFET 1Q. In the region 2A, the extension region EX2 and the diffusion region ND constitute a source region or a drain region of the ferroelectric memory transistor MQ.

Next, by performing an isotropic etching treatment using an aqueous solution containing hydrofluoric acid, the silicon oxide film OX2 and the cap film CP1 are removed in the region 1A, and the insulating film IF1 exposed from the sidewall spacer SW2 and the cap film CP1 are removed in the region 2A.

Thereafter, a silicide film SI is formed on an upper surface of each of the diffusion region ND, the gate electrode GE1, and the gate electrode GE2 by a salicide technique. The silicide film SI is made of, for example, cobalt silicide (CoSi₂), nickel silicide (NiSi), or nickel platinum silicide (NiPtSi). Through the above manufacturing steps, the MISFET 10 and the ferroelectric memory transistor MQ illustrated in FIG. 1 are manufactured.

### Modification

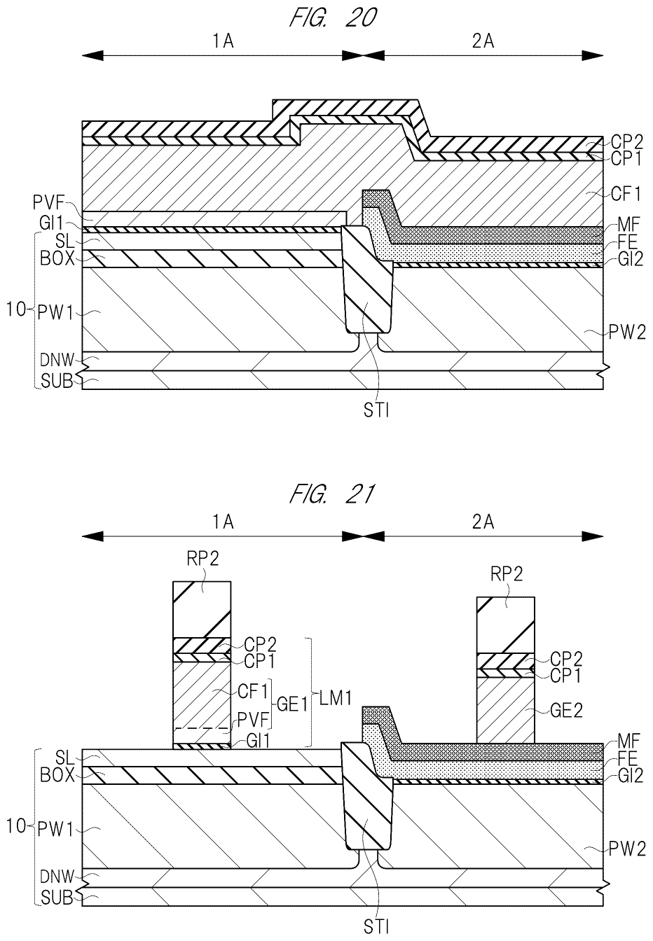

A modification of the first embodiment will be described below with reference to FIGS. 18 to 22. In the first embodiment, the protective film PVF is removed, but in the modification, the protective film PVF is left as a part of the gate electrode GE1.

FIG. 18 illustrates a manufacturing step subsequent to FIG. 3. As illustrated in FIG. 18, first, the semiconductor layer SL and the insulating layer BOX located in the region 2A are selectively removed using a photolithography technique and an etching treatment so as to leave the semiconductor layer SL and the insulating layer BOX located in the region 1A. As a result, the semiconductor substrate SUB located in the region 2A is exposed.

Next, the gate insulating film GIL is formed on the semiconductor layer SL located in the region 1A and on the semiconductor substrate SUB located in the region 2A by a thermal oxidation treatment. Next, the protective film PVF is formed on the gate insulating film GI1 located in the region 1A and the region 2A by a film forming treatment using, for example, a CVD method. The protective film PVF is an n-type polycrystalline silicon film.

As illustrated in FIG. 19, the protective film PVF and the gate insulating film GI1 located in the region 2A are selectively removed.

First, a resist pattern RP5 that opens the region 2A and covers the region 1A is formed on the protective film PVF. Next, by performing an anisotropic etching treatment using the resist pattern RP5 as a mask, the protective film PVF exposed from the resist pattern RP5 is removed. Next, by performing an isotropic etching treatment using the resist pattern RP5 as a mask, the gate insulating film GI1 exposed from the resist pattern RP5 is removed. As a result, the semiconductor substrate SUB located in the region 2A is exposed. Next, the resist pattern RP5 is removed by an ashing treatment.

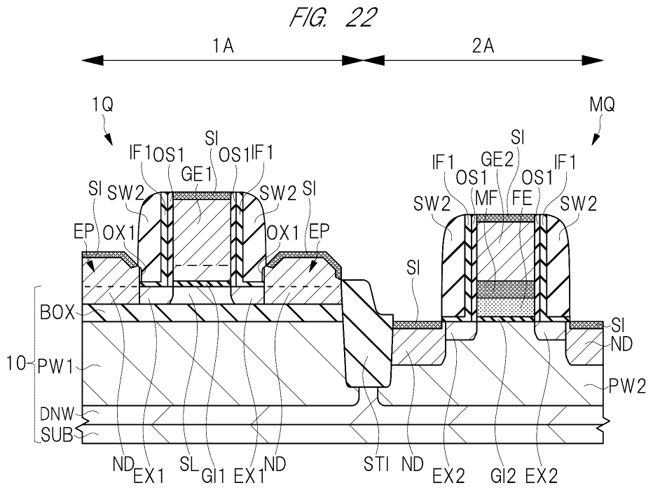

As illustrated in FIG. 20, first, the gate insulating film GI2, the ferroelectric film FE, and the metal film MF are formed using a method similar to that in FIGS. 5 and 6 of the first embodiment. In the modification, the metal film MF and the ferroelectric film FE located in the region 1A are selectively removed, but the protective film PVF located in the region 1A is left without being removed.

Next, the conductive film CF1, the cap film CP1, and the cap film CP2 are sequentially formed on the protective film PVF located in the region 1A and on the metal film MF located in the region 2A using a method similar to that in FIG. 7 of the first embodiment.

As illustrated in FIG. 21, the protective film PVF, the conductive film CF1, the cap film CP1, and the cap film CP2 are patterned.

First, in the region 1A and the region 2A, the resist pattern RP2 is formed so as to cover a part of the cap film CP2. Next, by performing an anisotropic etching treatment using the resist pattern RP2 as a mask, the cap film CP2, the cap film CP1, the conductive film CF1, and the protective film PVF exposed from the resist pattern RP2 are removed in the region 1A, and the cap film CP2, the cap film CP1, and the conductive film CF1 exposed from the resist pattern RP2 are removed in the region 2A. Next, the resist pattern RP2 is removed by an ashing treatment.

The conductive film CF1 and the protective film PVF patterned in the region 1A are formed as the gate electrode GE1, and the conductive film CF1 patterned in the region 2A is formed as the gate electrode GE2. Next, by performing an isotropic etching treatment using an aqueous solution containing hydrofluoric acid, the gate insulating film GI1 exposed from the gate electrode GE1 in the region 1A may be removed.

In this manner, a stacked structure LM1 including the gate insulating film GI1, the gate electrode GE1, the cap film CP1, and the cap film CP2 is formed on the semiconductor layer SL located in the region 1A.

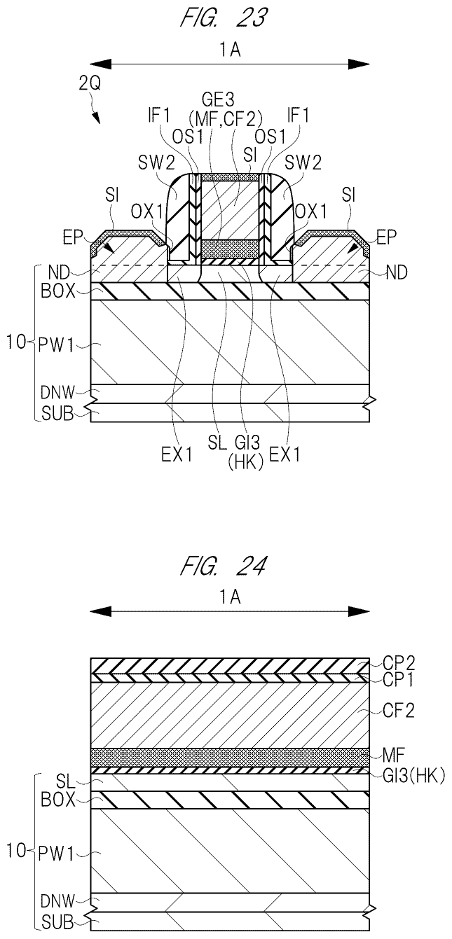

Thereafter, the MISFET 10 and the ferroelectric memory transistor MQ illustrated in FIG. 22 are manufactured through manufacturing steps similar to those in FIGS. 10 to 17 of the first embodiment.

### Second Embodiment

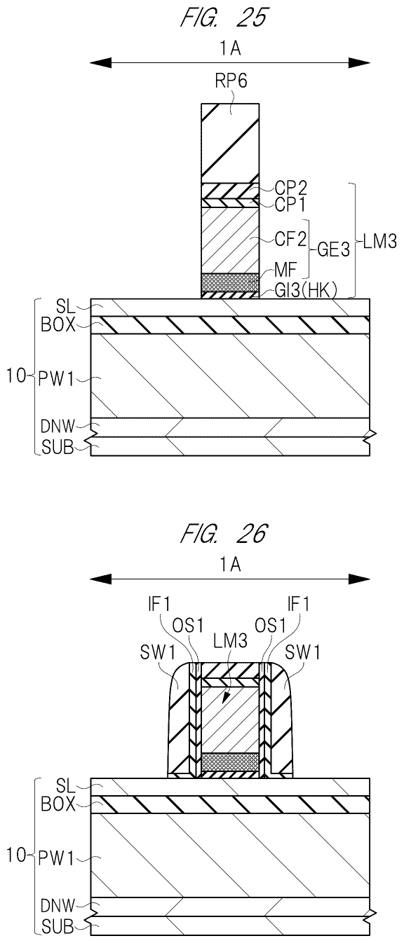

A part of a structure of a semiconductor device in a second embodiment will be described below with reference to FIG. 23. In addition, each manufacturing step included in a method of manufacturing the semiconductor device in the second embodiment will be described below with reference to FIGS. 24 to 31. Note that, in the following description, a difference from the first embodiment will be mainly described, and description of a point overlapping with the first embodiment will be omitted.

As illustrated in FIG. 23, in the second embodiment, a MISFET 20 is formed in the region 1A. The MISFET 20 is a low breakdown voltage MISFET constituting a logic circuit, an SRAM circuit, and the like similarly to the MISFET 1Q. The MISFET 2Q has the same configuration as the MISFET 10 except that a configuration of a gate insulating film GI3 and a configuration of a gate electrode GE3 are different from the configuration of the gate insulating film GI1 and the configuration of the gate electrode GE1, respectively.

The MISFET 20 includes the gate insulating film GI3 and the gate electrode GE3. The gate insulating film GI3 includes a silicon oxide film and a high dielectric constant film HK. The high dielectric constant film HK is made of an insulating film having a higher dielectric constant than silicon nitride. The gate electrode GE3 includes a metal film MF and a conductive film CF2 made of an n-type polycrystalline silicon film.

Also in the second embodiment, there is a possibility that a defect may occur in the concern portion 20 and the concern portion 21 as in the examined example of FIG. 31, but such a defect can be eliminated by forming the silicon oxide film OX1 and a cleaning treatment using an aqueous solution containing ammonia water and an activator.

Each manufacturing step included in the method of manufacturing the semiconductor device in the second embodiment will be described below. FIG. 24 illustrates a manufacturing step subsequent to FIG. 3.

As illustrated in FIG. 24, the gate insulating film GI3, the metal film MF, the conductive film CF2, a cap film CP1, and a cap film CP2 are formed.

First, the gate insulating film GI3 is formed on a semiconductor layer SL located in a region 1A. In order to form the gate insulating film GI3, first, a silicon oxide film is formed on the semiconductor layer SL by a thermal oxidation treatment using, for example, an ISSG oxidation method. The silicon oxide film is formed for the purpose of stabilizing an interface state between the semiconductor layer SL and the gate insulating film GI3, and has a thickness of, for example, 1 nm or more and 2 nm or less.

Next, the high dielectric constant film HK is formed on the silicon oxide film by a film forming treatment, for example, using an ALD method. The high dielectric constant film HK has a thickness of, for example, 4 nm or more and 10 nm or less. The high dielectric constant film HK is, for example, a hafnium oxide film (HfO₂ film), a hafnium silicate film (HfSiO film), an aluminum oxide film (Al₂O₃ film), a hafnium aluminate film (HfAlO₂ film), or a stacked film thereof.

Next, the metal film MF is formed on the gate insulating film GI3 by a film forming treatment using, for example, a CVD method or a sputtering method. The metal film MF of the second embodiment may be made of the same material as the metal film MF of the first embodiment, or may be made of a material different from the metal film MF of the first embodiment. The metal film MF of the second embodiment is, for example, a titanium nitride film, a titanium film, a tantalum nitride film, a tantalum film, a tungsten nitride film, a tungsten film, an aluminum film, or a stacked film thereof.

Next, the conductive film CF2, the cap film CP1, and the cap film CP2 are sequentially formed on the metal film MF by a film forming treatment using, for example, a CVD method. The conductive film CF2 is, for example, an n-type polycrystalline silicon film.

Next, as illustrated in FIG. 25, a resist pattern RP6 is formed so as to cover a part of the cap film CP2. Next, by performing an anisotropic etching treatment using the resist pattern RP6 as a mask, the cap film CP2, the cap film CP1, the conductive film CF2, the metal film MF, and the gate insulating film GI3 exposed from the resist pattern RP6 are removed. Next, the resist pattern RP6 is removed by an ashing treatment.

In this manner, a stacked structure LM3 including the gate insulating film GI3, the gate electrode GE3 including the conductive film CF2 and the metal film MF, the cap film CP1, and the cap film CP2 is formed on the semiconductor layer SL.

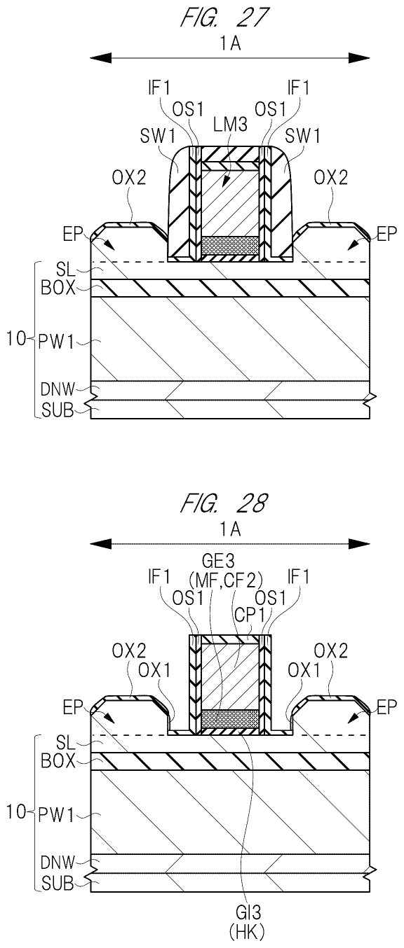

Next, as illustrated in FIG. 26, an offset spacer OS1, an insulating film IF1, and a sidewall spacer SW1 are formed on a side surface of the stacked structure LM3 using a method similar to that of the first embodiment.

Next, as illustrated in FIG. 27, an epitaxial layer EP is formed on the semiconductor layer SL exposed from the stacked structure LM3, the insulating film IF1, and the sidewall spacer SW1 using a method similar to that of the first embodiment. Next, a silicon oxide film OX2 is formed on a surface of the epitaxial layer EP exposed from the sidewall spacer SW1 using a method similar to that of the first embodiment.

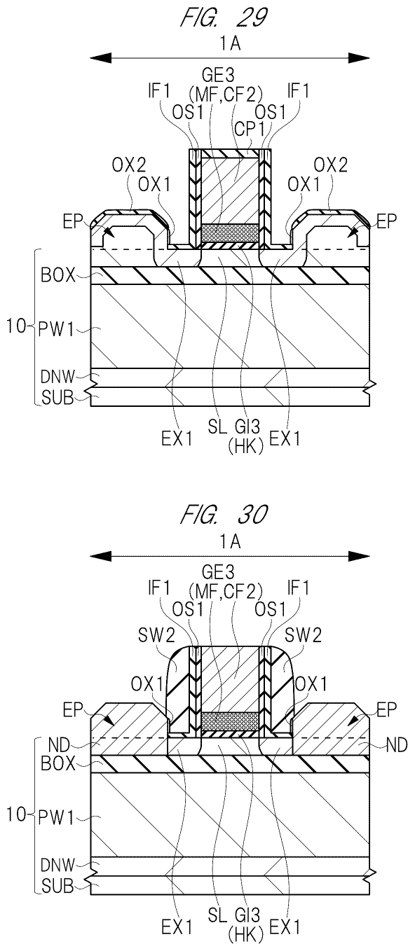

Next, as illustrated in FIG. 28, the sidewall spacer SW1 and the cap film CP2 of the stacked structure LM3 are removed by an anisotropic etching treatment. At this time, a part of a surface of the epitaxial layer EP in contact with the sidewall spacer SW1 is exposed.

Next, a silicon oxide film OX1 is formed on a surface of the epitaxial layer EP exposed from the insulating film IF1 and the silicon oxide film OX2. A method of forming the silicon oxide film OX1 is the same as that in the first embodiment, and is, for example, an ashing treatment or a thermal oxidation treatment.

Next, as illustrated in FIG. 29, a cleaning treatment similar to that of the first embodiment is performed on the insulating film IF1, the silicon oxide film OX1, and the silicon oxide film OX2. Next, by performing the ion implantation so as to pass through the insulating film IF1, the silicon oxide film OX1, and the silicon oxide film OX2, an n-type extension region EX1 is formed in the semiconductor layer SL and the epitaxial layer EP.

Also in the second embodiment, the problem that the metal film MF is dissolved can be solved, and the problem that a part of each of the epitaxial layer EP, the semiconductor layer SL, and the gate electrode GE3 is removed can be solved as in the first embodiment. As a result, reliability of the semiconductor device can be improved.

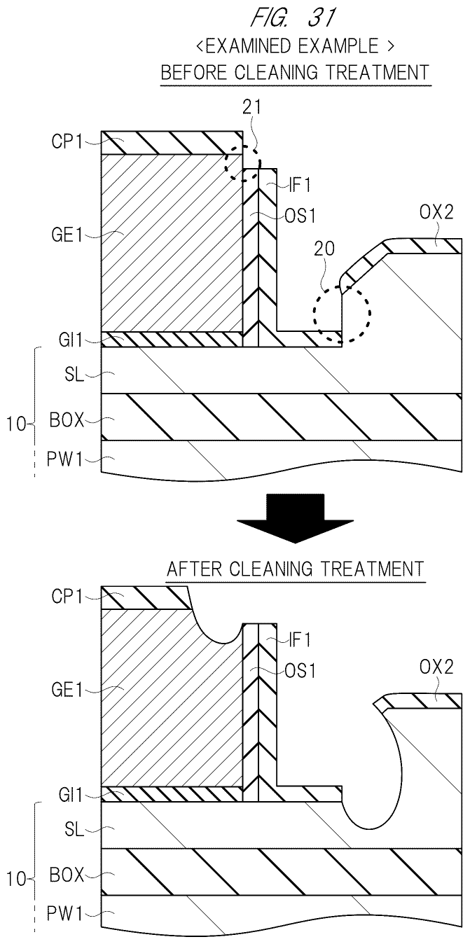

Next, as illustrated in FIG. 30, a sidewall spacer SW2 and a diffusion region ND are formed using a method similar to that of the first embodiment, and the silicon oxide film OX2 and the cap film CP1 are removed.

Thereafter, a silicide film SI is formed using a method similar to that of the first embodiment. Through the above manufacturing steps, the MISFET 20 illustrated in FIG. 23 is manufactured.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

For example, in the above embodiments, the n-type MISFET 1Q and the n-type MISFET 20 have been described, but the present invention can also be applied to a case where the MISFET 1Q and the MISFET 2Q are p-type. In such a case, the conductivity types of the components included in the MISFET 10 and the MISFET 2Q are opposite conductivity types, for example, the extension region EX1 is a p-type impurity region.

What is claimed is:

1. A method of manufacturing a semiconductor device having a first region in which a first MISFET is formed and a second region in which a second MISFET is formed, the method comprising:
(a) preparing an SOI substrate including a semiconductor substrate, an insulating layer formed on the semiconductor substrate, and a semiconductor layer formed on the insulating layer;
(b) after the (a), in the first region, forming a first stacked structure including a first gate insulating film, a first gate electrode formed on the first gate insulating film, and a first cap film formed on the first gate electrode;
(c) after the (a), in the second region, forming a second stacked structure including a second gate insulating film, a metal film formed on the second gate insulating film, a second gate electrode formed on the metal film, and a second cap film formed on the second gate electrode;
(d) after the (b) and the (c), forming a first insulating film so as to cover the first stacked structure and the second stacked structure;
(e) after the (d), in each of the first region and the second region, forming a second insulating film on the first insulating film;
(f) after the (e), in the first region, forming a first sidewall spacer on a side surface of the first stacked structure via the first insulating film by selectively processing the second insulating film, and removing the first insulating film exposed from the first sidewall spacer;
(g) after the (f), in the first region, forming an epitaxial layer on the semiconductor layer exposed from the first stacked structure, the first insulating film, and the first sidewall spacer;
(h) after the (g), removing the first sidewall spacer in the first region, and removing the second insulating film in the second region;
(i) after the (h), in the first region, forming a first silicon oxide film on a surface of the epitaxial layer exposed from the first insulating film;
(j) after the (i), reducing a thickness of each of the first insulating the first silicon oxide film by performing a cleaning treatment using an aqueous solution containing ammonia and an activator on each of the first insulating film and the first silicon oxide film; and
(k) after the (j), in the first region, forming a first impurity region in each of the semiconductor layer and the epitaxial layer by performing an ion implantation so as to pass through each of the first insulating film and the first silicon oxide film.

2. The method of manufacturing the semiconductor device according to claim 1,
wherein the aqueous solution used in the (j) does not contain hydrogen peroxide water.

3. The method of manufacturing the semiconductor device according to claim 1,
wherein, in the (i), the first silicon oxide film is formed by performing an ashing treatment.

4. The method of manufacturing the semiconductor device according to claim 3,
wherein the (k) is performed after the (i) and the (j) are repeated a plurality of times.

5. The method of manufacturing the semiconductor device according to claim 1,
wherein, in the (i), the first silicon oxide film is formed by performing a thermal oxidation treatment.

6. The method of manufacturing the semiconductor device according to claim 1,
wherein, in the (d), the first insulating film is formed by a film forming treatment using a CVD method.

7. The method of manufacturing the semiconductor device according to claim 1, further comprising:
(l) after the (g) and before the (h), forming a second silicon oxide film on the surface of the epitaxial layer exposed from the first sidewall spacer,
wherein, in the (i), in the first region, the first silicon oxide film is formed on the surface of the epitaxial layer exposed from each of the first insulating film and the second silicon oxide film,
wherein, in the (j), a thickness of the second silicon oxide film is also reduced by the cleaning treatment, and
wherein, in the (k), the ion implantation is performed so as to pass through also the second silicon oxide film.

8. The method of manufacturing the semiconductor device according to claim 1, further comprising:
(m) after the (a) and before the (b) and the (c), in the second region, selectively removing each of the semiconductor layer and the insulating layer,
wherein, in the (b), the first stacked structure is formed on the semiconductor layer located in the first region, and
wherein, in the (c), the second stacked structure is formed on the semiconductor substrate located in the second region.

9. The method of manufacturing the semiconductor device according to claim 1,
wherein the metal film is a titanium nitride film.

10. The method of manufacturing the semiconductor device according to claim 1,
wherein the second stacked structure includes a ferroelectric film formed on the second gate insulating film,
wherein the metal film is formed on the ferroelectric film and functions as a part of the second gate electrode, and
wherein the second MISFET is a ferroelectric memory transistor.

11. A method of manufacturing a semiconductor device, comprising:
(a) preparing an SOI substrate including a semiconductor substrate, an insulating layer formed on the semiconductor substrate, and a semiconductor layer formed on the insulating layer;
(b) after the (a), forming, on the semiconductor layer, a first stacked structure including a first gate insulating film, a first gate electrode including a metal film formed on the first gate insulating film, and a first cap film formed on the first gate electrode;
(c) after the (b), forming a first insulating film so as to cover the first stacked structure;
(d) film after the (c), forming a second insulating film on the first insulating;
(e) after the (d), forming a first sidewall spacer on a side surface of the first stacked structure via the first insulating film by processing the second insulating film, and removing the first insulating film exposed from the first sidewall spacer;
(f) after the (e), forming an epitaxial layer on the semiconductor layer exposed from the first stacked structure, the first insulating film, and the first sidewall spacer;
(g) after the (f), removing the first sidewall spacer;
(h) after the (g), forming a first silicon oxide film on a surface of the epitaxial layer exposed from the first insulating film;
(i) after the (h), reducing a thickness of each of the first insulating film and the first silicon oxide film by performing a cleaning treatment using an aqueous solution containing ammonia and an activator on the first insulating film and the first silicon oxide film; and
(j) after the (i), forming a first impurity region in each of the semiconductor layer and the epitaxial layer by performing an ion implantation so as to pass through each of the first insulating film and the first silicon oxide film.

12. The method of manufacturing the semiconductor device according to claim 11,
wherein the aqueous solution used in the (i) does not contain hydrogen peroxide water.

13. The method of manufacturing the semiconductor device according to claim 12,
wherein, in the (h), the first silicon oxide film is formed by performing an ashing treatment.

14. The method of manufacturing the semiconductor device according to claim 13,
wherein, the (j) is performed after the (h) and the (i) are repeated a plurality of times.

15. The method of manufacturing the semiconductor device according to claim 11,
wherein, in the (h), the first silicon oxide film is formed by performing a thermal oxidation treatment.

16. The method of manufacturing the semiconductor device according to claim 11,
wherein, in the (c), the first insulating film is formed by a film forming treatment using a CVD method.

17. The method of manufacturing the semiconductor device according to claim 11, further comprising
(k) forming a second silicon oxide film on the surface of the epitaxial layer exposed from the first sidewall spacer between the (f) and the (g),
wherein, in the (h), the first silicon oxide film is formed on the surface of the epitaxial layer exposed from each of the first insulating film and the second silicon oxide film,
wherein, in the (i), a thickness of the second silicon oxide film is also reduced by the cleaning treatment, and
wherein, in the (j), the ion implantation is performed so as to pass through also the second silicon oxide film.

18. The method of manufacturing the semiconductor device according to claim 11,
wherein the metal film is a titanium nitride film, a titanium film, a tantalum nitride film, a tantalum film, a tungsten nitride film, a tungsten film, an aluminum film, or a stacked film thereof.

19. The method of manufacturing the semiconductor device according to claim 11,
wherein, the first gate insulating film includes a high dielectric constant film made of an insulating film having a higher dielectric constant than silicon nitride.
